(19) United States
(12) Patent Application Publication
(10) Pub. No.: US 2024/0038703 A1
(43) Pub. Date: Feb. 1, 2024

(54) SEMICONDUCTOR ASSEMBLY INCLUDING MULTIPLE SOLDER MASKS

(71) Applicant: ATI TECHNOLOGIES ULC, MARKHAM (CA)

(72) Inventors: JIANGUO LI, MARKHAM (CA); RODEN R. TOPACIO, MARKHAM (CA)

(21) Appl. No.: 17/878,271

(22) Filed: Aug. 1, 2022

(51) Int. Cl. H01L 23/00

(52) U.S. Cl. CPC H01L 24/10; H01L 24/05; H01L 24/13; H01L 24/11; H01L 2224/05573; H01L 2224/05567; H01L 2224/05647; H01L 2224/10145; H01L 2224/03334; H01L 2224/03849; H01L 2224/13007; H01L 2224/13005; H01L 2224/13016; H01L 2224/10175

(57) ABSTRACT

A semiconductor device includes a substrate and a conductive pad coupled to the substrate. A first solder mask is coupled to the substrate and to a portion of the conductive pad so the first solder mask covers the portion of the conductive pad and extends above the conductive pad. A second solder mask is coupled to a portion of the first solder mask and extends above the first solder mask.

### BACKGROUND

In semiconductor assemblies, such as package assemblies or printed circuit boards, solder joints are used to connect components to each other. As a number of components included in a semiconductor assembly increases, distance between solder joints decreases. This increases a likelihood of solder bridging between adjacent connections where solder creates an electrical short between adjacent components when a solder joint is being formed.

### BRIEF DESCRIPTION OF THE DRAWINGS

FIG. 1A is part of a process flow for manufacturing a semiconductor assembly including multiple solder masks according to some implementations.

FIG. 1B is part of a process flow for manufacturing a semiconductor assembly including multiple solder masks according to some implementations.

FIG. 1C is part of a process flow for manufacturing a semiconductor assembly including multiple solder masks according to some implementations.

FIG. 1D is part of a process flow for manufacturing a semiconductor assembly including multiple solder masks according to some implementations.

FIG. 2 is an example structure for a first solder mask and a second solder mask according to some implementations.

FIG. 3 is an example structure for a first solder mask and a second solder mask according to some implementations.

FIG. 4 is a cross-sectional diagram of an example integrated circuit device including a semiconductor assembly having multiple solder masks according to some implementations.

FIG. 5 is an example computing device according to some implementations.

FIG. 6 is a flow chart illustrating an example method for manufacturing a semiconductor assembly including multiple solder masks according to some implementations.

### DETAILED DESCRIPTION

When fabricating a semiconductor package or a printed circuit board design, solder joints may be used to electrically connect different components. Solder joints are formed by applying a solder ball to a conductive pad and heating the solder ball to form a solder joint. As an increasing number of components are included in a semiconductor package or on a printed circuit board, a likelihood of solder ball bridging, where adjacent solder joints bridge together and cause a short circuit, also increases.

Conventional fabrication techniques reduce a risk of solder ball bridging by reducing a size of a solder ball or a size of an opening in the substrate for the solder ball. However, such reductions reduce reliability of a resulting solder joint. Similarly, for printed circuit boards, the opening for a solder ball or a thickness of the solder ball is reduced to mitigate the risk of solder ball bridging, which similarly decreases reliability of the resulting solder joint.

To that end, the present specification sets forth various implementations of a semiconductor device including a substrate and a conductive pad coupled to the substrate. The semiconductor device also includes a first solder mask coupled to the substrate and coupled to a portion of the conductive pad, where the first solder mask covers the portion of the conductive pad and extends above the conductive pad. The semiconductor device further includes a second solder mask coupled to a portion of the first solder mask, where the second solder mask extends above the first solder mask. In some implementations, the first solder mask and the second solder mask comprise different materials.

In some implementations, the semiconductor device further includes a solder ball contacting an additional portion of the conductive pad that is not covered by the solder mask, where the solder ball is within an area having a boundary formed by the second solder mask. The second solder mask is positioned to prevent solder from the solder ball spreading outside the area bounded by the second solder mask in some implementations. In some implementations, a combined height of the first solder mask and the second solder mask is within a threshold amount of a height of the solder ball. In other implementations, the second solder mask is coupled to the first solder mask in a location within a threshold distance of a plane perpendicular to the edge of the conductive pad.

In some implementations, a portion of the second solder mask is coupled to an additional portion of the conductive pad of the semiconductor device, where the additional portion of the conductive pad is not covered by the first solder mask.

In some implementations, the first solder mask and the second solder mask comprise a common material. In other implementations, the first solder mask and the second solder mask comprise different materials. In some implementations, the portion of the solder mask coupled to the additional portion of the conductive pad decreases a diameter of a solder joint formed from a solder ball contacting another portion of the conductive pad that is not covered by the solder mask and that is not covered by the second solder mask.

In some embodiments, the semiconductor device further includes an additional second solder mask opposite the second solder mask and parallel to the second solder mask, where the additional second solder mask is coupled to an additional portion of the first solder mask and extends above the first solder mask. In some implementations, the additional second solder mask is positioned between the conductive pad and an additional conductive pad adjacent to the conductive pad. The second solder mask is coupled to the first solder mask in a location within a threshold distance of a plane perpendicular to the edge of the conductive pad in some implementations.

The present specification also describes a method that includes applying a first solder mask to a substrate and to a conductive pad coupled to the substrate, where the first solder mask covers a portion of the conductive pad and extends above the conductive pad. The method further includes applying a second solder mask to the first solder mask, where the second solder mask is coupled to a portion of the first solder mask and extends above the first solder mask.

In some implementations, applying the second solder mask to the first solder mask includes coupling a portion of the second solder mask to an additional portion of the conductive pad, where the additional portion of the conductive pad is not covered by the first solder mask. In some implementations, the portion of the second solder mask coupled to the additional portion of the conductive pad decreases a diameter of a solder joint formed from a solder ball contacting another portion of the conductive pad that is not covered by the first solder mask and that is not covered by the second solder mask. In some implementations, applying the second solder mask to the first solder mask includes coupling the second solder mask to the first solder mask in a location within a threshold distance of a plane perpendicular to the edge of the conductive pad.

In some implementations, the method further includes applying a solder ball to the conductive pad, so the solder ball contacts an additional portion of the conductive pad that is not covered by the solder mask and the solder ball is within an area having a boundary formed by the second solder mask. The method further includes melting the solder ball, with melted solder remaining within the area having the boundary formed by the second solder mask in some implementations.

In some implementations applying the second solder mask to the first solder mask includes applying a second solder mask layer to a surface of the first solder mask and to a surface of the conductive pad not covered by the first solder mask and forming the second solder mask by removing one or more portions of the second solder mask layer from the surface of the first solder mask and the surface of the conductive pad not covered by the first solder mask.

In some implementations, the first solder mask and the second solder mask comprise different materials.

The following disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows include implementations in which the first and second features are formed in direct contact, and also include implementations in which additional features formed between the first and second features, such that the first and second features are in direct contact. Further, spatially relative terms, such as “beneath,” “below,” “lower,” “above,” “upper,” “back,” “front,” “top,” “bottom,” and the like, are used herein for ease of description to describe one element or feature's relationship to another element(s) or feature(s) as illustrated in the figures. Similarly, terms such as “front surface” and “back surface” or “top surface” and “back surface” are used herein to more easily identify various components, and identify that those components are, for example, on opposing sides of another component. The spatially relative terms are intended to encompass different orientations of the device in use or operation in addition to the orientation depicted in the figures.

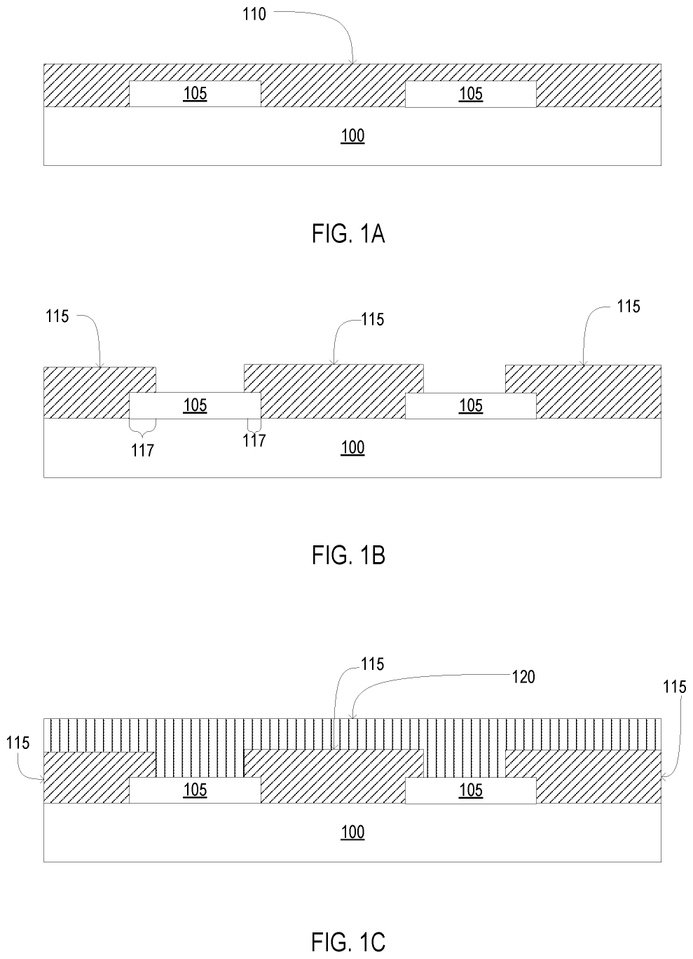

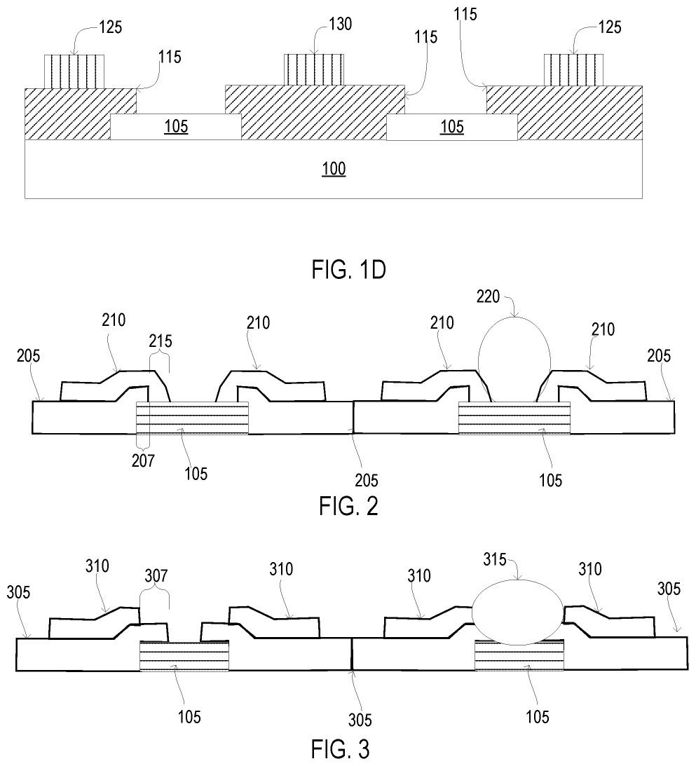

FIGS. 1A-1D show steps in an example manufacturing process for a semiconductor assembly including multiple solder masks. Beginning with FIG. 1A, one or more conductive pads 105 are coupled to, or applied to, a substrate 100. Each conductive pad 105 comprises an electrically conductive material. For example, a conductive pad 105 comprises copper, while in other examples the conductive pad 105 comprises one or more other conductive materials. In various embodiments, the substrate 100 comprises materials such as glass fiber core material, pre-preg, build up material, epoxy, conductive material (e.g., copper), or other suitable materials. A first solder mask layer 110 is applied to a surface of the substrate 100 and to a surface of the one or more conductive pads 105. The first solder mask layer 110 has a thickness so an upper surface of the first solder mask layer 110 (relative to the substrate 100) has a height above the surface of the substrate 100 and the surface of the one or more conductive pads 105 to which the first solder mask layer 110 was applied. The first solder mask layer 110 has different thicknesses in different implementations. The first solder mask layer 110 is a non-electrically conductive material. For example, the first solder mask layer 110 is epoxy or polymer in some implementations.

As shown in FIG. 1B, portions of the first solder mask layer 110 are removed, resulting in a first solder mask 115, with openings in the first solder mask 115 where portions of the one or more conductive pads 105 are exposed, being coupled to the substrate. In various embodiments, the portions of the first solder mask layer 110 are removed using photolithography, while other methods are used to remove portions of the first solder mask layer 110 in other implementations. A pattern is used to identify portions of the first solder mask layer 110 to remove in various implementations. As shown in FIG. 1B, the first solder mask 115 covers a portion 117 of a conductive pad 105. The solder mask 115 also extends above the conductive pad 105. In different implementations, the height with which the first solder mask 115 extends above the conductive pad 105 differs.

Referring to FIG. 1C, a second solder mask layer 120 is applied to the first solder mask 115. As shown in the implementation of FIG. 1C, the second solder mask layer 120 is applied to a surface of the first solder mask 115 and to a surface of the one or more conductive pads 105. The second solder mask layer 120 has a thickness so an upper surface of the second solder mask layer 120 (relative to the one or more conductive pads 105) has a height above the surface of the first solder mask 115 and the surface of the one or more conductive pads 105 to which the second solder mask layer 120 was applied. The second solder mask layer 120 has different thicknesses in different implementations. The second solder mask layer 120 is a non-electrically conductive material. For example, the second solder mask layer 120 is epoxy or polymer in some implementations. In some implementations, the second solder mask layer 120 a film material, while in other implementations the second solder mask layer 120 is a liquid material (e.g., epoxy liquid, liquid ink). In some implementations, the first solder mask 115 and the second solder mask layer 120 are a common material, while in other implementations, the first solder mask 115 comprises a different material than the second solder mask layer 120.

In FIG. 1D, portions of the second solder mask layer 120 are removed, resulting in a second solder mask 125, with openings in the second solder mask 125 where portions of the one or more conductive pads 105 are exposed. In various embodiments, the portions of the second solder mask layer 120 are removed using photolithography, while other methods are used to remove portions of the second solder mask layer 120 in other implementations. A pattern is used to identify portions of the second solder mask layer 120 to remove in various implementations. The second solder mask 125 is coupled to a portion of the first solder mask 115, with the second solder mask 125 extending above the first solder mask 115. In different implementations, the height with which the second solder mask 125 extends above the first solder mask 115 differs. Extending above the first solder mask 115 allows the second solder mask 125, along with the first solder mask 115, to form a boundary for solder applied to the position of a conductive pad 105 that is not covered by the first solder mask 115. Such a boundary prevents solder applied to the exposed portion of a conductive pad 105 from bridging to an adjacent conductive pad 105 and creating an electrical short. In some implementations a combined height of the first solder mask 115 and the second solder mask 125 is within a threshold amount of a height of a solder ball applied to the exposed portion of the conductive pad 105. In other implementations, the combined height of the first solder mask 115 and the second solder mask 125 equals the height of the solder ball applied to the exposed portion of the conductive pad 105, while in other implementations, the combined height of the first solder mask 115 and the second solder mask exceeds the height of the solder ball applied to the exposed portion of the conductive pad.

In various implementations, the height of the second solder mask 125 ranges between 20 microns and 50 microns. The second solder mask 125 has different widths in different implementations, with a size of a ball grid array and solder resist opening for a conductive pad 105 affecting a width of the second solder mask. For example, the second solder mask 125 has a range of widths between 100 microns and 400 microns.

In some implementations, such as shown in FIG. 1D, an additional second solder mask 130 is opposite the second solder mask 125 and parallel to the second solder mask 125. For example, the second solder mask 125 and the additional second solder mask 130 are on opposing sides of a conductive pad 105 to form a boundary for solder on multiple sides of the conductive pad 105. The additional second solder mask 130 is coupled to an additional portion of the first solder mask 115 and extends above the first solder mask 115. In various implementations, the additional second solder mask 130 is positioned between the conductive pad 105 and an additional conductive pad 105 that is adjacent to the conductive pad 105 to prevent solder from contacting the additional conductive pad 105.

While FIGS. 1A-1D show a first solder mask 115 and a second solder mask 125 coupled to the second solder mask 125, in some implementations, additional solder masks may be coupled to the second solder mask 125 to further increase a height above a conductive pad 105 to which the combination of solder masks extends. Although FIGS. 1A-1D show the formation of the first solder mask 115 and the second solder mask 125 with respect to a substrate 100, in other implementations the one or more conductive pads 105 are coupled to a printed circuit board, so the first solder mask 115 is coupled to the printed circuit board and to portions of the one or more conductive pads in such implementations.

Various implementations may employ different structures for the first solder mask 115 or for the second solder mask 125. FIGS. 2 and 3 depict different example structures for the first solder mask 115 and for the second solder mask 125 for purposes of illustration. For clarity, FIGS. 2 and 3 do not show the substrate 100 to which the one or more conductive pads 105 are coupled. In the example of FIG. 2, a first solder mask 205 is coupled to a substrate (not shown) and covers a portion 207 of a conductive pad 105. As shown in FIG. 2, the first solder mask 205 extends above the conductive pad 105 by a height. In the example shown by FIG. 2, a second solder mask 210 is coupled to a portion of the first solder mask 210 and extends above the first solder mask 205 by an amount. Further, in the implementation of FIG. 2, the second solder mask 210 is also coupled to an additional portion 215 of the conductive pad 105, where the additional portion 215 of the conductive pad 105 is not covered by the first solder mask 205. Coupling the second solder mask 210 to the additional portion 215 of the conductive pad 105 reduces an amount of the conductive pad 105 that is exposed, which reduces a diameter of a solder joint formed from a solder ball 220 that contacts the portion of the conductive pad 105 that is exposed (i.e., not covered by the first solder mask 205 and not covered by the second solder mask 210). Additionally, the second solder mask 210 is positioned relative to the conductive pad 105 so the solder ball 220 is within an area bounded by the second solder mask 210 and so solder from the solder ball 220 is prevented from spreading outside the area bounded by the second solder mask 210. Thus, in the example shown by FIG. 2, solder from the solder ball 220 is blocked from reaching a conductive pad 105 adjacent to the conductive pad the solder ball 220 contacts by the second solder mask 210, preventing solder bridging.

In the example of FIG. 3, a first solder mask 305 is coupled to a substrate (not shown) and covers a portion 307 of a conductive pad 105. As shown in FIG. 3, the first solder mask 305 extends above the conductive pad 105 by a height. In the example shown by FIG. 3, a second solder mask 310 is coupled to a portion of the first solder mask 305 and extends above the first solder mask 305 by an amount. In the implementation of FIG. 3, the second solder mask 310 is not coupled to a portion of the conductive pad 105. For example, the second solder mask 310 is coupled to the first solder mask 305 in a location corresponding to an edge of the conductive pad 105 or in a location within a threshold distance of a plane perpendicular to the edge of the conductive pad 105. When a solder ball 315 contacts a conductive pad 105, the solder ball 315 is an area that has a boundary formed by the second solder mask 310, which prevents solder from the solder ball 315 from spreading outside the area bounded by the second solder mask 310, preventing solder from the solder ball 315 from reaching a conductive pad 105 adjacent to the conductive pad the solder ball 315 contacts by the second solder mask 310. While FIGS. 2 and 3 show example configurations of the first solder mask and the second solder mask, different configurations of the first solder mask and the second solder mask are possible in other implementations.

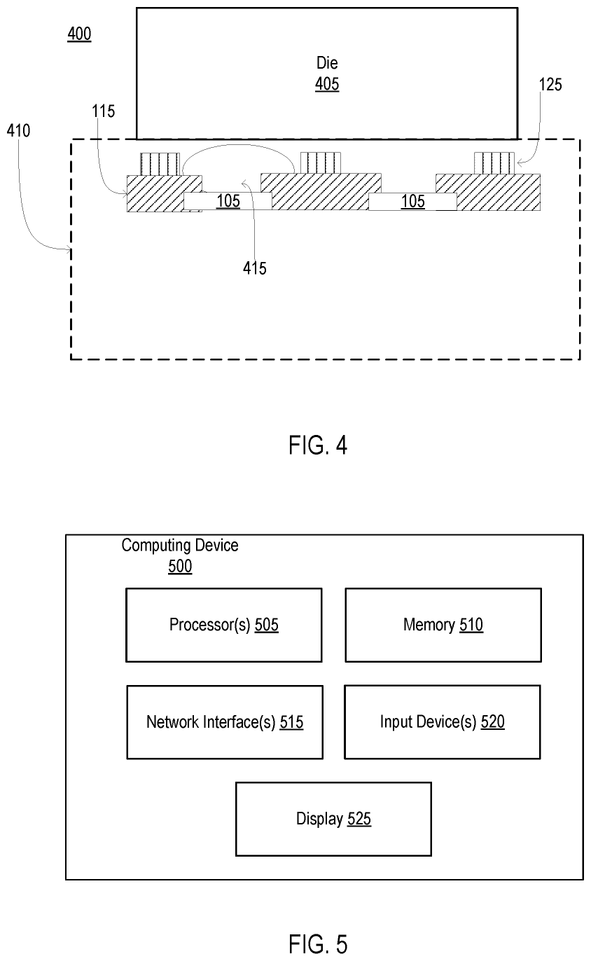

FIG. 4 is a cross-sectional diagram of an example integrated circuit device 400 including multiple solder masks in accordance with some implementations of the present disclosure. The example integrated circuit device 400 can be implemented in a variety of computing devices, including mobile devices, personal computers, peripheral hardware components, gaming devices, set-top boxes, smart phones, and the like (as shown in FIG. 5). The example integrated circuit device 400 of FIG. 4 includes a die 405. The die 405 is a block of semiconducting material such as silicon onto which a functional integrated circuit is fabricated. As an example, the die 405 includes a processor such as a Central Processing Unit (GPU), a Graphics Processing Unit (GPU), or other processor as can be appreciated.

As an example, the die 405 includes a processor 505 of a computing device 500 as shown in FIG. 5. The computing device 500 is implemented, for example, as a desktop computer, a laptop computer, a server, a game console, a smart phone, a tablet, and the like. In addition to one or more processors 505, the computing device 500 includes memory 510. The memory 510 includes Random Access Memory (RAM) or other volatile memory. The memory 510 also includes non-volatile memory such as disk storage, solid state storage, and the like.

In some implementations, the computing device 500 also includes one or more network interfaces 515. In some implementations, the network interfaces 515 include a wired network interface 515 such as Ethernet or another wired network connection as can be appreciated. In some implementations, the network interfaces 515 include wireless network interfaces 515 such as WiFi, BLUETOOTH®, cellular, or other wireless network interfaces 515 as can be appreciated. In some implementations, the computing device 500 includes one or more input devices 520 that accept user input. Example input devices 520 include keyboards, touchpads, touch screen interfaces, and the like. One skilled in the art will appreciate that, in some implementations, the input devices 520 include peripheral devices such as external keyboards, mouses, and the like.

In some implementations, the computing device 500 includes a display 525. In some implementations, the display 525 includes an external display connected via a video or display port. In some implementations, the display 525 is housed within a housing of the computing device 500. For example, the display 525 includes a screen of a tablet, laptop, smartphone, or other mobile device. In implementations where the display 525 includes a touch screen, the display 525 also serves as an input device 520.

The die 405 is coupled to a substrate 410. The substrate 410 is a portion of material that mechanically supports coupled components such as the die 405. In some implementations, the substrate 410 also electrically couples various components mounted to the substrate 410 via conductive traces, tracks, pads, and the like. For example, the substrate 410 electrically couples a component of the die 405 to one or more other components via a connective trace and a solder joint formed from a solder ball 415 coupled to a conductive pad 105. As further described above in conjunction with FIGS. 1A-1D, to prevent the solder joint from bridging to another solder joint, the substrate 410 includes a first solder mask 115 and a second solder mask 125. As further described above in conjunction with FIGS. 1A-3, the second solder mask 125 is coupled to the first solder mask 115 and extends above the first solder mask 115 to form a boundary of an aera where the solder ball 415, and solder from the solder ball 415, occupies. This prevents solder from the solder ball 415 reaching a conductive pad 105 other than the conductive pad 105 that the solder ball 415 contacts.

In some implementations, the substrate 410 includes a printed circuit board (PCB), while in other implementations the substrate 410 is another semiconductor device, like die 405 (which may include active components therein). In some implementations, the die 405 is coupled to the substrate 410 via a socket (not shown), where the die 405 is soldered to or otherwise mounted in the socket. In other implementations, as shown in FIG. 4, the die 405 is directly coupled to the substrate 410 via a direct solder connection or other connection as can be appreciated. In some implementations, the die 405 is coupled to the substrate 410 using a land grid array (LGA), pin grid array (PGA), or other packaging technology as can be appreciated.

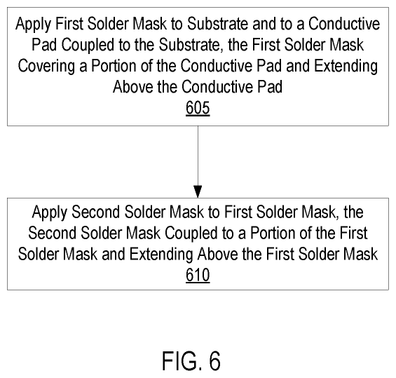

For further explanation, FIG. 6 sets forth a flow chart illustrating an example method for manufacturing an integrated circuit device assembly for a semiconductor assembly including multiple solder masks according to implementations of the present disclosure. The method of FIG. 6 includes applying 605 a first solder mask 115 to a substrate 100 and to a conductive pad 105 that is coupled to the substrate 100. The first solder mask 115 covers a portion of the conductive pad 105 and extends above the conductive pad 105, as shown in FIGS. 1A and 1B.

A second solder mask 125 is applied 610 to the first solder mask 115, with the second solder mask 125 coupled to a portion of the first solder mask 115 and extending above the first solder mask 115, as shown in FIGS. 1C-3. Hence, the second solder mask 125 is coupled to the first solder mask 115, while extending above the first solder mask 115. In some implementations, a second solder mask layer 120 is applied to a surface of the first solder mask 115 and to a surface of the conductive pad 105 that is not covered by the first solder mask 115, and the second solder mask 125 is formed by removing one or more portions of the second solder mask layer 120 from the surface of the first solder mask 115 and from the surface of the conductive pad 105 that is not covered by the first solder mask 115. Further, in some implementations, such as the example shown in FIG. 1B, when applying the second solder mask 125 to the first solder mask 115, a portion of the second solder mask 125 is coupled to an additional portion of the conductive pad 105 that is not covered by the first solder mask 115. The first solder mask 115 and the second solder mask 125 comprise different materials in some implementations, while in other implementations the first solder mask 115 and the second solder mask 125 comprise different materials.

When a solder ball is applied to the conductive pad 105, the solder ball contacts the conductive pad 105 that is not covered by the first solder mask 115 (or by the second solder mask 125). The solder ball remains within an area that has a boundary formed by the second solder mask 125, allowing the first solder mask 115 and the second solder mask 125 to prevent the solder ball from contacting an adjacent solder ball or an adjacent conductive pad 105. When the solder ball is melted, melted solder remains within the area having the boundary formed by the second solder mask 125, preventing the melted solder from contacting other conductive pads 105 or other components.

In view of the explanations set forth above, readers will recognize that manufacturing an integrated circuit device assembly including multiple solder masks allows solder joints to be isolated from other solder joints or conductive pads, such as adjacent solder joints or adjacent conductive pads. This reduces a likelihood of solder bridging in the integrated circuit device assembly that electrically shorts different components. Using multiple solder masks reduces the likelihood of solder bridging without compromising solder joint reliability.

It will be understood from the foregoing description that modifications and changes can be made in various implementations of the present disclosure. The descriptions in this specification are for purposes of illustration only and are not to be construed in a limiting sense. The scope of the present disclosure is limited only by the language of the following claims.

What is claimed is:

1. A semiconductor device comprising:
a substrate;
a conductive pad coupled to the substrate;
a first solder mask coupled to the substrate and coupled to a portion of the conductive pad, the first solder mask covering the portion of the conductive pad and extending above the conductive pad; and
a second solder mask coupled to a portion of the first solder mask, the second solder mask extending above the first solder mask.

2. The semiconductor device of claim 1, further comprising:
a solder ball contacting an additional portion of the conductive pad that is not covered by the solder mask, the solder ball within an area having a boundary formed by the second solder mask.

3. The semiconductor device of claim 2, wherein the second solder mask is positioned to prevent solder from the solder ball spreading outside the area bounded by the second solder mask.

4. The semiconductor device of claim 2, wherein a combined height of the first solder mask and the second solder mask is within a threshold amount of a height of the solder ball.

5. The semiconductor device of claim 1, wherein a portion of the second solder mask is coupled to an additional portion of the conductive pad, where the additional portion of the conductive pad is not covered by the first solder mask.

6. The semiconductor device of claim 5, wherein the portion of the second solder mask coupled to the additional portion of the conductive pad decreases a diameter of a solder joint formed from a solder ball contacting another portion of the conductive pad that is not covered by the solder mask and that is not covered by the second solder mask.

7. The semiconductor device of claim 1, wherein the first solder mask and the second solder mask comprise a common material.

8. The semiconductor device of claim 1, wherein the first solder mask and the second solder mask comprise different materials.

9. The semiconductor device of claim 1, further comprising:
an additional second solder mask opposite the second solder mask and parallel to the second solder mask, the additional second solder mask coupled to an additional portion of the first solder mask and extending above the first solder mask.

10. The semiconductor device of claim 9, wherein the additional second solder mask is positioned between the conductive pad and an additional conductive pad adjacent to the conductive pad.

11. The semiconductor device of claim 1, wherein the second solder mask is coupled to the first solder mask in a location within a threshold distance of a plane perpendicular to the edge of the conductive pad.

12. A method for forming semiconductor assembly comprising:
applying a first solder mask to a substrate and to a conductive pad coupled to the substrate, the first solder mask covering a portion of the conductive pad and extending above the conductive pad; and
applying a second solder mask to the first solder mask, the second solder mask coupled to a portion of the first solder mask and extending above the first solder mask.

13. The method of claim 12, wherein applying the second solder mask to the first solder mask comprises:
coupling a portion of the second solder mask to an additional portion of the conductive pad, where the additional portion of the conductive pad is not covered by the first solder mask.

14. The method of claim 13, wherein the portion of the second solder mask coupled to the additional portion of the conductive pad decreases a diameter of a solder joint formed from a solder ball contacting another portion of the conductive pad that is not covered by the solder mask and that is not covered by the second solder mask.

15. The method of claim 12, wherein applying the second solder mask to the first solder mask comprises:
coupling the second solder mask to the first solder mask in a location within a threshold distance of a plane perpendicular to the edge of the conductive pad.

16. The method of claim 12, further comprising:
applying a solder ball to the conductive pad, the solder ball contacting an additional portion of the conductive pad that is not covered by the solder mask and the solder ball within an area having a boundary formed by the second solder mask.

17. The method of claim 16, further comprising:
melting the solder ball, with melted solder remaining within the area having the boundary formed by the second solder mask.

18. The method of claim 12, further comprising:
applying an additional second solder mask to opposite to the second solder mask and parallel to the second solder mask, the additional second solder mask coupled to an additional portion of the first solder mask and extending above the first solder mask.

19. The method of claim 12, wherein applying the second solder mask to the first solder mask comprises:
applying a second solder mask layer to a surface of the first solder mask and to a surface of the conductive pad not covered by the first solder mask; and
forming the second solder mask by removing one or more portions of the second solder mask layer from the surface of the first solder mask and the surface of the conductive pad not covered by the first solder mask.

20. The method of claim 12, wherein the first solder mask and the second solder mask comprise different materials.
